(19) United States
(12) Patent Application Publication
(10) Pub. No.: US 2025/0072103 A1
(43) Pub. Date: Feb. 27, 2025

(54) SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 18/749,591

(22) Filed: Jun. 20, 2024

(30) Foreign Application Priority Data
Aug. 24, 2023 (JP) 2023-136693

(51) Int. Cl. H01L 27/07; H01L 29/06; H01L 29/10; H01L 29/739; H01L 29/861

(52) U.S. Cl. CPC H01L 27/0727; H01L 29/0611; H01L 29/1004; H01L 29/7397; H01L 29/8613

(57) ABSTRACT

Provided is a semiconductor device including: a front surface electrode provided above the semiconductor substrate; a trench contact portion at which the front surface electrode and the mesa portion are connected to each other in the transistor portion; and a front surface contact portion at which the front surface electrode and the mesa portion are connected to each other in the diode portion, where a lower end of the front surface contact portion is arranged above a lower end of the trench contact portion.

### BACKGROUND

### 1. Technical Field

The present invention relates to a semiconductor device.

### 2. Related Art

In a semiconductor device including a transistor portion and a diode portion, the structure of a contact of a trench shape connecting an electrode and a semiconductor substrate is known (for example, refer to Patent Literatures 1 and 2).
Patent Literature 1: WO 2018/056233
Patent Literature 2: Japanese Patent Application Publication No. 2021-150483

### BRIEF DESCRIPTION OF THE DRAWINGS

FIG. 1 is a plan view showing an example of a semiconductor device 100.

FIG. 2 is an enlarged view of a region D in FIG. 1.

FIG. 3A is a diagram showing an example of a cross section e-e in FIG. 2.

FIG. 3B is an enlarged view of the vicinity of the second mesa portion 62 and the third mesa portion 63 shown in FIG. 3A.

FIG. 4A is a diagram showing an example of a cross section f-f in FIG. 2.

FIG. 4B is an enlarged view of the vicinity of the second mesa portion 62 and the third mesa portion 63 shown in FIG. 4A.

FIG. 5 is a diagram showing an example a P type doping concentration distribution of the anode region 84 and the second plug region 222 in the vicinity of the front surface of the third mesa portion 63.

FIG. 6 is a plan view showing another example of FIG. 2.

FIG. 7A is a diagram showing an example of a cross section g-g in FIG. 6.

FIG. 7B is a diagram showing an example of cross section h-h in FIG. 6.

FIG. 8 is a plan view showing another example of FIG. 2.

FIG. 9A is a diagram showing an example of a cross section j-j in FIG. 8.

FIG. 9B is a diagram showing an example of a cross section k-k in FIG. 8.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

A region from the center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is No and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. In the present specification, the VOH defect or interstitial Si—H may be referred to as a hydrogen donor.

In the semiconductor substrate in the present specification, bulk donors of the N type are distributed throughout. A bulk donor is a dopant donor substantially uniformly contained in an ingot during the manufacture of the ingot from which the semiconductor substrate is made. The bulk donor in the present example is an element other than hydrogen. The bulk donor dopant is, but not limited to, for example, phosphorous, antimony, arsenic, selenium, or sulfur. The bulk donor in the present example is phosphorous. The bulk donor is contained also in a region of the P type. The semiconductor substrate may be a wafer cut out from a semiconductor ingot, or may be a chip obtained by singulating the wafer. The semiconductor ingot may be manufactured by any of a Czochralski method (CZ method), a magnetic field applied Czochralski method (MCZ method), or a float zone method (FZ method). The ingot in the present example is manufactured by the MCZ method. A concentration of oxygen contained in the substrate manufactured by the MCZ method is 1×10¹⁷ to 7×10¹⁷/cm³. The concentration of oxygen contained in the substrate manufactured by the FZ method is 1×10¹⁵ to 5×10¹⁶/cm³. When the concentration of oxygen is higher, hydrogen donors tend to be more easily generated. As a bulk donor concentration, a chemical concentration of the bulk donors distributed throughout the semiconductor substrate may be used, and the bulk donor concentration may have a value between 90% and 100% of the chemical concentration. In addition, as the semiconductor substrate, a non-doped substrate not containing a dopant such as phosphorous may be used. In that case, a bulk donor concentration (DO) of the non-doped substrate is, for example, 1×10¹⁰/cm³ or greater and 5×10¹²/cm³ or smaller. The bulk donor concentration (DO) of the non-doped substrate is preferably 1×10¹¹/cm³ or greater. The bulk donor concentration (DO) of the non-doped substrate is preferably 5×10¹²/cm³ or smaller. It should be noted that each concentration in the present invention may have a value at a room temperature. As the value at a room temperature, a value at 300K (Kelvin) (about 26.9 degrees C.) as an example may be used.

In the present specification, a description of a P+ type or an N+ type means a higher doping concentration than that of the P type or the N type, and a description of a P− type or an N-type means a lower doping concentration than that of the P type or the N type. Further, in the specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

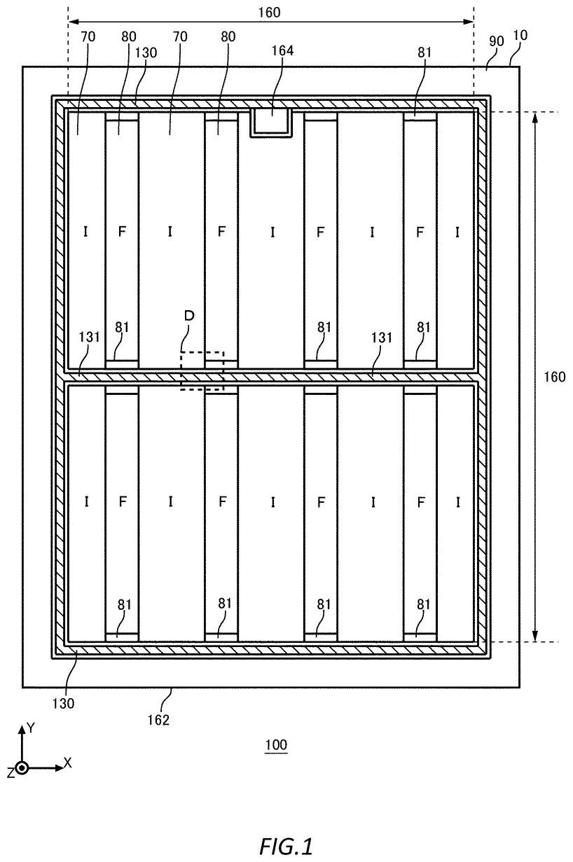

FIG. 1 is a plan view showing an example of a semiconductor device 100. FIG. 1 illustrates a position of each member as being projected onto a front surface of a semiconductor substrate 10. FIG. 1 shows only a part of members of the semiconductor device 100, and omits other members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has end sides 162 in a top view. As simply used herein, unless otherwise specified, a top view means a view from the side of the front surface of the semiconductor substrate 10. The semiconductor substrate 10 in the present example has two sets of end sides 162 opposite to each other in a top view. In FIG. 1, the X axis and the Y axis are parallel to any of the end sides 162. In addition, the Z axis is perpendicular to the front surface of the semiconductor substrate 10.

The semiconductor substrate 10 is provided with an active portion 160. The active portion 160 is a region where a principal current flows in the depth direction between the front surface and the back surface of the semiconductor substrate 10 when the semiconductor device 100 operates. An emitter electrode is provided above the active portion 160, but illustration thereof is omitted in FIG. 1. The active portion 160 may refer to a region that overlaps with the emitter electrode in the top view. In addition, a region sandwiched between active portions 160 in a top view may also be included in the active portion 160.

The active portion 160 is provided with a transistor portion 70 including a transistor element such as an insulated gate bipolar transistor (IGBT) and a diode portion 80 including a diode element such as a freewheeling diode (FWD). In the example of FIG. 1, the transistor portions 70 and the diode portions 80 are arrange alternately along the predetermined first direction on the front surface of the semiconductor substrate 10 (the X axis direction in the present example). The semiconductor device 100 in the present example is a reverse conducting IGBT (RC-IGBT). A boundary region is arranged between the transistor portion 70 and the diode portion 80 in the X axis direction, but is omitted in FIG. 1.

In FIG. 1, a region where a transistor portion 70 is arranged is marked with a symbol “I”, and a region where a diode portion 80 is arranged is marked with a symbol “F”. In the present specification, a direction different from the first direction in the top view may be referred to as a second direction (the Y axis direction in FIG. 1). The second direction may be a direction perpendicular to the first direction. Each of the transistor portion 70 and the diode portion 80 may have a longitudinal length in the second direction. In other words, the length of each of the transistor portions 70 in the Y axis direction is larger than the width in the X axis direction. Similarly, the length of each of the diode portions 80 in the Y axis direction is larger than the width in the X axis direction. The second direction of the transistor portion 70 and the diode portion 80 may be the same as a longitudinal direction of each trench portion and a longitudinal direction of a mesa portion described below.

The diode portion 80 includes a cathode region of N+ type in a region in contact with the back surface of the semiconductor substrate 10. In the present specification, a region where the cathode region is provided is referred to as the diode portion 80. In other words, the diode portion 80 is a region that overlaps with the cathode region in the top view. The back surface of the semiconductor substrate 10 may be provided with a collector region of P+ type in a region other than the cathode region. In the present specification, the diode portion 80 may also include an extension region 81 where the diode portion 80 extends to a gate runner described below in the Y axis direction. The back surface of the extension region 81 is provided with the collector region. The diode portion 80 includes an anode region of a P− type in the front surface side of the semiconductor substrate 10.

The transistor portion 70 includes a collector region of a P+ type in a region in contact with the back surface of the semiconductor substrate 10. In addition, the transistor portion 70 includes emitter regions of the N+ type, contact regions of the P+ type, base regions of the P− type, and gate structures including gate conductive portions and gate dielectric films in the front surface side of the semiconductor substrate 10, which are arranges at regular intervals.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in the vicinity of an end side 162. The vicinity of the end side 162 refers to a region between the end side 162 and the emitter electrode in a top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of the present example includes an outer circumferential gate runner 130. The outer circumferential gate runners 130 are arranged between the active portion 160 and the end sides 162 of the semiconductor substrate 10 in a top view. The outer circumferential gate runners 130 of the present example enclose the active portion 160 in a top view. A region enclosed by the outer circumferential gate runners 130 in a top view may be the active portion 160. In addition, a well region is formed below the gate runner. The well region is the P type region having a concentration higher than that of the base region described below and formed from the front surface of the semiconductor substrate 10 to a position deeper than the base region. A region enclosed by the well region in a top view may be the active portion 160.

The outer circumferential gate runner 130 is connected to the gate pad 164. The outer circumferential gate runner 130 is arranged above the semiconductor substrate 10. The outer circumferential gate runner 130 may be a metal wiring including aluminum or the like.

The semiconductor device 100 of the present example further includes an active side gate runner 131. The active side gate runner 131 is provided in the active portion 160. Providing the active side gate runner 131 in the active portion 160 can reduce a variation in wiring line length from the gate pad 164 for each region of the semiconductor substrate 10.

The outer circumferential gate runner 130 and the active side gate runner 131 are connected to the gate trench portion of the active portion 160. The outer circumferential gate runner 130 and the active side gate runner 131 are arranged above the semiconductor substrate 10. The outer circumferential gate runner 130 and the active side gate runner 131 may be a wiring formed of a semiconductor such as polysilicon doped with an impurity.

The active side gate runner 131 may be connected to the outer circumferential gate runner 130. The active side gate runner 131 of the present example is provided extending in the X axis direction so as to cross the active portion 160 substantially at a center of the Y axis direction, from one of the outer circumferential gate runners 130 sandwiching the active portion 160 to the other. When the active portion 160 is divided by the active side gate runner 131, the transistor portions 70 and the diode portions 80 may be alternately arranged in the X axis direction in each region obtained by the division.

The semiconductor device 100 may include a temperature sensing portion (not shown) which is a PN junction diode formed of polysilicon or the like, and a current detection portion (not shown) which simulates an operation of a transistor portion provided in the active portion 160. The semiconductor device 100 in the present example includes an edge termination

structure portion 90 between the active portion 160 and the end sides 162 in a top view. The edge termination structure portion 90 in the present example is arranged between the outer circumferential gate runners 130 and the end sides 162. The edge termination structure portion 90 reduces concentration of electric fields on the side of the front surface of the semiconductor substrate 10. The edge termination structure portion 90 may include at least one of a guard ring, a field plate, and an RESURF which are annularly provided enclosing the active portion 160.

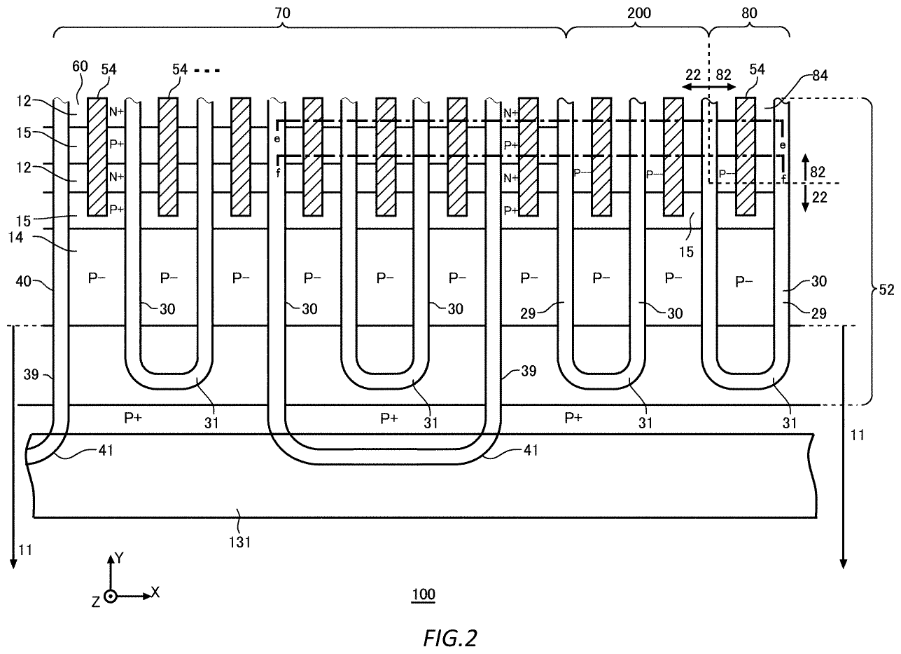

FIG. 2 illustrates an enlarged view of a region D in FIG. 1. The region D is a region including a transistor portion 70, a diode portion 80, and an active side gate runner 131. Although omitted in FIG. 1, a boundary region 200 is arranged between the transistor portion 70 and the diode portion 80 in the X axis direction. The boundary region 200 is a region including a collector region of the P+ type in a region in contact with the back surface of the semiconductor substrate 10. The area ratio of the emitter region 12 of the boundary region 200 is smaller than that of the transistor portion 70. The boundary region 200 of the present example does not include an emitter region on the front surface of the semiconductor substrate 10. A width of the boundary region 200 of the present example in the X axis direction is equal to or greater than 20 μm and equal to or smaller than 250 μm.

The semiconductor device 100 of the present example includes a gate trench portion 40, a dummy trench portion 30, a well region 11, an emitter region 12, a base region 14, a contact region 15, and an anode region 84 that are provided inside the front surface side of the semiconductor substrate 10. The gate trench portion 40 and the dummy trench portion 30 each are an example of the trench portion. In addition, the semiconductor device 100 of the present example includes an emitter electrode 52 and the active side gate runner 131 that are provided above the front surface of the semiconductor substrate 10. The emitter electrode 52 and the active side gate runner 131 are provided to be separated from each other.

An interlayer dielectric film is provided between the emitter electrode 52 and the active side gate runner 131, and the front surface of the semiconductor substrate 10, but the interlayer dielectric film is omitted in FIG. 2.

The interlayer dielectric film of the present example includes a contact hole 54 provided to extend therethrough. In FIG. 2, each of the contact holes 54 is hatched with diagonal lines.

The emitter electrode 52 is provided above the gate trench portion 40, the dummy trench portion 30, the well region 11, the emitter region 12, the base region 14, the contact region 15, and the anode region 84. The emitter electrode 52 is in contact with the emitter region 12, the contact region 15, and the base region 14 on the front surface of the semiconductor substrate 10, through the contact hole 54. In addition, the emitter electrode 52 is connected to dummy conductive portions in the dummy trench portions 30 through the contact holes provided in the interlayer dielectric film. The emitter electrode 52 may be connected to the dummy conductive portions of the dummy trench portions 30 at edges of the dummy trench portions 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active side gate runner 131 is connected to the gate trench portions 40 through the contact holes provided in the interlayer dielectric film. The active side gate runner 131 may be connected to gate conductive portions of the gate trench portions 40 at edge portions 41 of the gate trench portions 40 in the Y axis direction. The active side gate runner 131 is not connected to the dummy conductive portions in the dummy trench portions 30.

The emitter electrode 52 is formed of a material containing a metal. The emitter electrode 52 is an example of the front surface electrode. FIG. 2 shows a range where the emitter electrode 52 is provided. For example, at least a partial region of the emitter electrode 52 is formed of aluminum or an alloy containing aluminum as a main component, such as a metal alloy of Al—Si or Al—Si—Cu, for example. The emitter electrode 52 may include a barrier metal. In addition, the front surface electrode may include a contact plug portion in the contact hole including: a barrier metal formed of titanium and titanium compounds and the like on the side surface of the contact hole; and a plug formed by filling tungsten and the like to be in contact with the barrier metal and the emitter electrode 52. The contact plug portion connects the emitter electrode 52 and the semiconductor substrate 10.

The well region 11 is provided overlapping the active side gate runner 131. The well region 11 is provided extending with a predetermined width also in a range not overlapping the active side gate runner 131. The well region 11 in the present example is provided away from ends of the contact holes 54 in the Y axis direction on an active side gate runner 131 side. The well region 11 is a region of a second conductivity type having a doping concentration higher than that of a base region 14. The base region 14 of the present example is a P− type, and the well region 11 is a P+ type.

Each of the transistor portion 70, the diode portion 80, and the boundary region 200 includes a plurality of trench portions arranged in the first direction. In the transistor portion 70 of the present example, one or more gate trench portions 40 and one or more dummy trench portions 30 are alternately provided along the first direction. In the diode portion 80 of the present example, the plurality of dummy trench portions 30 are provided along the first direction. In the diode portion 80 in the present example, the gate trench portion 40 is not provided. In the boundary region 200 of the present example, the plurality of dummy trench portions 30 are provided along the first direction. In the boundary region 200 of the present example, the gate trench portion 40 is not provided.

The gate trench portion 40 of the present example may have two linear portions 39 extending along the second direction perpendicular to the first direction (portions of a trench that are linear along the second direction), and the edge portion 41 connecting the two linear portions 39. The second direction in FIG. 2 is the Y axis direction.

At least a part of the edge portion 41 is preferably provided in a curved shape in a top view. Connecting end portions of the two linear portions 39 in the Y axis direction by the edge portion 41 can reduce electric field strengths at the end portions of the linear portions 39.

In the transistor portion 70, the dummy trench portions 30 are provided between the respective linear portions 39 of the gate trench portions 40. Between the respective linear portions 39, one dummy trench portion 30 may be provided or a plurality of dummy trench portions 30 may be provided. The transistor portion 70 of the present example is provided with two dummy trench portions 30 between the respective linear portions 39. The dummy trench portion 30 may have a straight shape extending in the second direction, or may have linear portions 29 and an edge portion 31 similar to the gate trench portion 40. The semiconductor device 100 shown in FIG. 2 only includes the dummy trench portion 30 including the edge portion 31, but may include both of the dummy trench portion 30 of a straight shape not including the edge portion 31 and the dummy trench portion 30 including the edge portion 31.

A diffusion depth of the well region 11 may be deeper than depths of the gate trench portion 40 and the dummy trench portion 30. End portions of the gate trench portion 40 and the dummy trench portion 30 in the Y axis direction are provided in the well region 11 in the top view. In other words, a bottom portion in a depth direction of each of the trench portions is covered with the well region 11 at an end portion in the Y axis direction of each of the trench portions. With this configuration, an electric field strength at the bottom portion of each of the trench portions can be reduced.

A mesa portion 60 is provided between the trench portions adjacent to each other in the first direction. The mesa portion 60 refers to a region sandwiched between the trench portions inside the semiconductor substrate 10. The front surface of the mesa portion 60 of the present example is the front surface of the semiconductor substrate 10. A depth position of a lower end of the mesa portion 60 is the same as a depth position of a lower end of the trench portion. The mesa portion 60 of the present example is provided to extend in the second direction (the Y axis direction) along the trench, on the front surface of the semiconductor substrate 10. The mesa portion 60 of the transistor portion 70, the mesa portion 60 of the diode portion 80, and the mesa portion 60 of the boundary region 200 may have different structures. When simply referred to as the mesa portion 60 in the present specification, it refers to each of the mesa portion 60 of the transistor portion 70, the mesa portion 60 of the diode portion 80, and the mesa portion 60 of the boundary region 200.

The mesa portion 60 of the transistor portion 70 is provided with the base region 14, while the mesa portions 60 of the diode portion 80 and the boundary region 200 are provided with the anode regions 84. While FIG. 2 shows the base region 14 arranged at one end portion of each mesa portion in the second direction, the base region 14 is also arranged at the other end portion of each mesa portion. The mesa portion 60 of the transistor portion 70 may be provided with at least one of the emitter region 12 of the first conductivity type and the contact region 15 of the second conductivity type in a region interposed between the base regions 14 in a top view. The emitter region 12 in the present example is of the N+ type, and the contact region 15 is of the P+ type. The emitter region 12 and the contact region 15 may be provided between the base region 14 and the front surface of the semiconductor substrate 10 in the depth direction.

The mesa portion 60 of the transistor portion 70 has an emitter region 12 exposed to the front surface of the semiconductor substrate 10. The emitter regions 12 are provided in contact with the gate trench portion 40. The mesa portion 60 in contact with the gate trench portion 40 may be provided with the contact region 15 exposed to the front surface of the semiconductor substrate 10.

Each of the contact region 15 and the emitter region 12 in the mesa portion 60 is provided from one trench portion to the other trench portion in the X axis direction. As an example, the contact regions 15 and the emitter regions 12 of the mesa portion 60 are alternately arranged along the second direction of the trench portion (the Y axis direction).

In another example, the contact regions 15 and the emitter regions 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12.

The mesa portion 60 of the diode portion 80 of the present example is not provided with the emitter region 12. An area ratio of the emitter region 12 in the mesa portion 60 in the boundary region 200 is smaller than an area ratio of the emitter region 12 in the mesa portion 60 of the transistor portion 70. The mesa portion 60 of the boundary region 200 of the present example is not provided with the emitter region 12.

The front surfaces of the mesa portions 60 of the diode portion 80 and the boundary region 200 may be provided with the anode regions 84. A doping concentration of the anode region 84 may be the same as or may be different from the doping concentration of the base region 14. A doping concentration of the anode region 84 of the present example is lower than a doping concentration of the base region 14. The base region 14 of the present example is of the P− type while the anode region 84 is of the P− type.

The mesa portion 60 of the boundary region 200 of the present example may include the anode region 84 which is the same as that of the mesa portion 60 of the diode portion 80. Note that the mesa portion 60 of the boundary region 200 may have a structure different from the anode region 84 or may include a P type impurity region having a doping concentration lower than that of the base region 14. The mesa portion 60 of the boundary region 200 is provided with a P type impurity region having a lower doping concentration to suppress the hole injection from the mesa portion 60 of the boundary region 200 so that the reverse recovery loss can be reduced.

In addition, the mesa portion 60 of the boundary region 200 may be provided with an N type impurity region having a doping concentration which is approximately the same as that of the emitter region 12 or lower than that of the emitter region 12, instead of the anode region 84. Note that in that case, the boundary region 200 is not provided with the gate trench portion 40. Moreover, the trench portion at the boundary position between the transistor portion 70 and the boundary region 200 is the dummy trench portion 30. In the mesa portion 60 of the boundary region 200, the N type impurity region is not in contact with the gate trench portion 40 so that the N type impurity region does not form an inversion layer to turn to be conductive. This can suppress the hole injection from the mesa portion 60 of the boundary region 200, thereby reducing the reverse recovery loss.

In addition, the mesa portions 60 of the boundary region 200 and the diode portion 80 may be provided the base region 14. Further, the contact region 15 may be provided in the front surface side of the base region 14 and the contact region 15 may be interposed between the base regions 14 in the Y axis direction. That is, an area ratio of the contact region 15 in the mesa portion 60 of the boundary region 200 may be greater than an area ratio of the contact region 15 in the mesa portion 60 of the diode portion 80. In this case, holes in the semiconductor substrate 10 are facilitated to be extracted to the emitter electrode 52 via the mesa portion 60 of the boundary region 200.

On the upper side of each mesa portion 60, the contact hole 54 is provided. The contact hole 54 is arranged in the region interposed between the base regions 14 or the anode regions 84. The contact hole 54 of the present example is provided above respective regions of the contact region 15, and the emitter region 12. The contact hole 54 is not provided in the base region 14 and the well region 11.

The contact hole 54 may be arranged at the center of the mesa portion 60 in the first direction (the X axis direction).

In the diode portion 80, a cathode region 82 of the N+ type is provided in a region in direct contact with the back surface of the semiconductor substrate 10. On the back surface of the semiconductor substrate 10, a region in which the cathode region 82 is not provided may be provided with a collector region 22 of the P+ type. The cathode region 82 and the collector region 22 are provided between the back surface 23 of the semiconductor substrate 10 and the buffer region 20. In FIG. 2, a boundary between the cathode region 82 and the collector region 22 is indicated by a dotted line.

The cathode region 82 is arranged away from the well region 11 in the Y axis direction. With this configuration, the distance between the P type region (the well region 11) having a relatively high doping concentration and formed up to the deep position, and the cathode region 82 is ensured, so that the breakdown voltage can be improved. An end portion of the cathode region 82 of the present example in the Y axis direction is arranged farther away from the well region 11 than an end portion of the contact hole 54 in the Y axis direction. In another example, the end portion of the cathode region 82 in the Y axis direction may be arranged between the well region 11 and the contact hole 54.

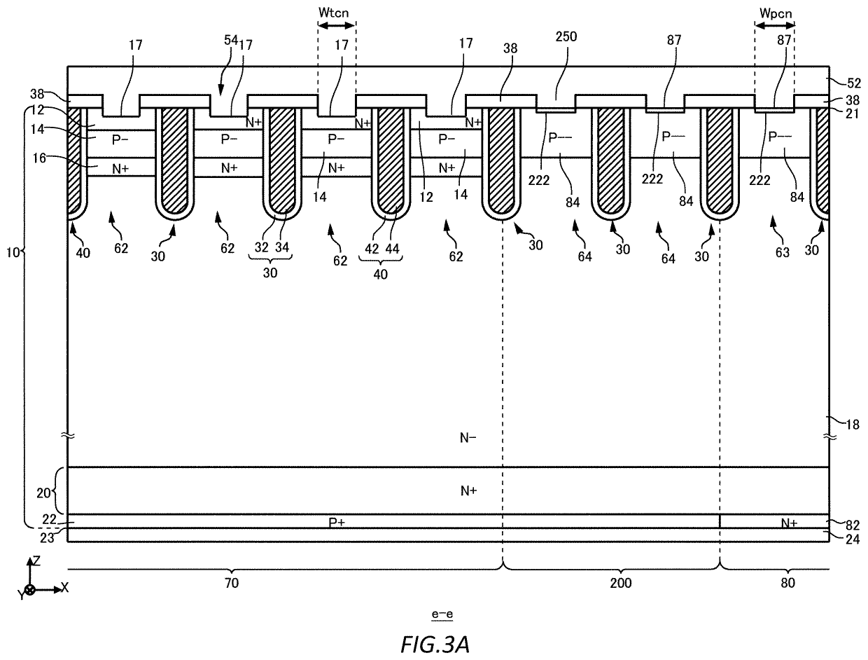

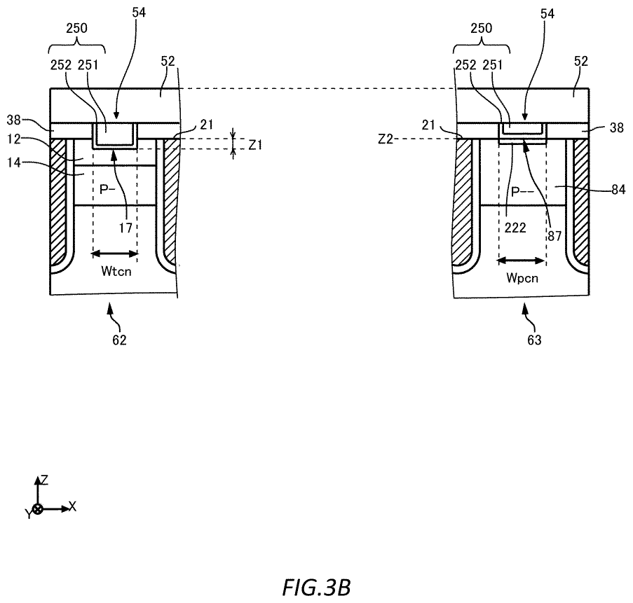

FIG. 3A illustrates a diagram showing an example of a cross section e-e in FIG. 2. The cross section e-e is an XZ plane passing through emitter regions 12 and a cathode region 82. A semiconductor device 100 in the present example has a semiconductor substrate 10, an interlayer dielectric film 38, an emitter electrode 52, and a collector electrode 24 in the cross section.

The interlayer dielectric film 38 is provided on a front surface of the semiconductor substrate 10. The interlayer dielectric film 38 is a film including at least one of a dielectric film such as silicate glass to which an impurity such as boron or phosphorous is added, a thermal oxide film, and another dielectric film. The interlayer dielectric film 38 is provided with the contact holes 54 described in FIG. 2.

The emitter electrode 52 is provided above the interlayer dielectric film 38. The emitter electrode 52 is an example of the front surface electrode. The emitter electrode 52 may be in contact with the semiconductor substrate 10 through the contact hole 54 of the interlayer dielectric film 38. Alternatively, the contact plug portion may be provided within the contact hole 54 to connect the emitter electrode 52 and the semiconductor substrate 10. The contact plug portion may include a plug formed of tungsten and the like and a barrier metal provided in a portion in contact with the semiconductor substrate 10 and including titanium. The barrier metal may include a titanium nitride layer and may have a stacked structure of the titanium nitride layer and the titanium layer.

The collector electrode 24 is provided on the back surface 23 of the semiconductor substrate 10. The emitter electrode 52 and the collector electrode 24 are formed of a metal material such as aluminum. In the present specification, a direction in which the emitter electrode 52 is connected to the collector electrode 24 (the Z axis direction) is referred to as a depth direction.

The semiconductor substrate 10 includes an N-type drift region 18. The drift region 18 is provided in each of the transistor portion 70, the diode portion 80, and the boundary region 200.

In the present example, a plurality of mesa portions 60 include a second mesa portion 62, a third mesa portion 63, and a fourth mesa portion 64. The second mesa portion 62 is provided in the transistor portion 70, the third mesa portion 63 is provided in the diode portion 80, and the fourth mesa portion 64 is provided in the boundary region 200.

In the second mesa portion 62 of the transistor portion 70, the emitter region 12 of the N+ type and the base region 14 of the P− type are provided in order from the front surface 21 side of the semiconductor substrate 10. The drift region 18 is provided below the base region 14. The second mesa portion 62 may be provided with an accumulation region 16 of the N+ type. The accumulation region 16 is arranged between the base region 14 and the drift region 18.

The emitter region 12 is exposed to the front surface 21 of the semiconductor substrate 10 and is provided in contact with the gate trench portion 40. The emitter region 12 may be in contact with trench portions on both sides of the mesa portion 60. The emitter region 12 has a higher doping concentration than the drift region 18.

The base region 14 is provided below the emitter region 12. The base region 14 in the present example is provided in contact with the emitter region 12. The base region 14 may be in contact with the trench portions on both sides of the second mesa portion 62.

The accumulation region 16 is provided below the base region 14. The accumulation region 16 is an N+ type region with a higher doping concentration than the drift region 18. That is, the accumulation region 16 has a donor concentration higher than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover the entire back surface of the base region 14 in the second mesa portion 62.

The third mesa portion 63 of the diode portion 80 is provided with the anode region 84 in contact with the front surface 21 of the semiconductor substrate 10. A doping concentration of the anode region 84 may be the same as a doping concentration of the base region 14, or may be lower than a doping concentration of the base region 14. A doping concentration of the anode region 84 in the present example is lower than a doping concentration of the base region 14. The base region 14 of the present example is of the P− type while the anode region 84 is of the P− type. The drift region 18 is provided below the anode region 84. The accumulation region 16 may also be provided below the anode region 84.

The fourth mesa portion 64 of the boundary region 200 of the present example is provided with the anode region 84 of the P− type in contact with the front surface 21 of the semiconductor substrate 10. The drift region 18 is provided below the anode region 84. In the fourth mesa portion 64, the accumulation region 16 may also be provided below the anode region 84.

In each of the transistor portion 70, the diode portion 80, and the boundary region 200, an N+ type buffer region 20 may be provided below the drift region 18. The doping concentration of the buffer region 20 is higher than the doping concentration of the drift region 18. The buffer region 20 may have a concentration peak of a doping concentration higher than that of the drift region 18. A doping concentration at the concentration peak refers to a doping concentration at a local maximum of the concentration peak. In addition, as the doping concentration in the drift region 18, an average doping concentration value in a region where a doping concentration distribution is substantially flat may be used.

The buffer region 20 may have two or more concentration peaks in the depth direction of the semiconductor substrate 10 (the Z axis direction). The concentration peaks of the buffer region 20 may be provided at the same depth position as that of, for example, a chemical concentration peak of hydrogen (a proton) or phosphorous. The buffer region 20 may function as a field stopper layer which prevents a depletion layer expanding from lower ends of base regions 14 from reaching a collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from that of the base region 14. The acceptor of the collector region 22 is, for example, boron.

In the diode portion 80, the cathode region 82 of the N+ type is provided below the buffer region 20. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the example described above.

In the boundary region 200, the collector region 22 of the P+ type is provided under the buffer region 20. That is, the boundary region 200 may be regarded as a part of the transistor portion 70. The collector region 22 of the boundary region 200 may have a doping concentration which is the same as that of the boundary region 200 of the transistor portion 70. A boundary position between the cathode region 82 and the collector region 22 in the X axis direction may be referred to as a boundary position between the diode portion 80 and the boundary region 200 in the X axis direction.

In another example, a part of or all of the collector region 22 of the boundary region 200 may be replaced with the cathode region 82. When the cathode region 82 is provided on the back surface of the boundary region 200, a region interposed between the anode regions 84 and including the contact regions 15 and the anode regions 84 arranged alternately therein may be referred to as the diode portion 80 while a region interposed between the anode regions 84 where the contact region 15 is arranged across the entire region may be referred to as the boundary region 200. When the cathode region 82 is provided on the back surface of the boundary region 200, the boundary region 200 may be regarded as a part of the diode portion 80.

Of two trench portions in contact with the emitter region 12 arranged to be closest to the diode portion 80 in the X axis direction, the trench portion at the diode portion 80 side may be the dummy trench portion 30. In this case, the dummy trench portion 30 may be a boundary position between the transistor portion 70 and the boundary region 200 (or the diode portion 80) in the X axis direction. The center position of the dummy trench portion 30 in the X axis direction may be a boundary position between the transistor portion 70 and the boundary region 200 (or the diode portion 80) in the X axis direction.

The boundary region 200 may alternatively be provided with the emitter region 12. Note that in that case, the boundary region 200 is not provided with the gate trench portion 40. Moreover, the trench portion at the boundary position between the transistor portion 70 and the boundary region 200 is the dummy trench portion 30. In other words, transistor operations do not occur in the boundary region 200. The boundary region 200 may alternatively be provided with the gate trench portion 40. Note that in that case, the boundary region 200 is not provided with the emitter region 12. In other words, transistor operations do not occur in the boundary region 200.

The collector region 22 and the cathode region 82 are exposed to the back surface 23 of the semiconductor substrate 10 and are connected to the collector electrode 24. The collector electrode 24 may be in contact with the entire back surface 23 of the semiconductor substrate 10. The emitter electrode 52 and the collector electrode 24 are formed of a metal material such as aluminum.

The one or more gate trench portions 40 and the one or more dummy trench portions 30 are provided in the front surface 21 side of the semiconductor substrate 10. Each trench portion is provided to extend from the front surface 21 of the semiconductor substrate 10 to a position below the base region 14 and the anode region 84, through the base region 14 or the anode region 84. In a region where at least any one of the emitter region 12, the contact region 15, and the accumulation region 16 is provided, each trench portion also passes through the doping regions of these. The configuration of the trench portion passing through the doping region is not limited to the one manufactured in the order of forming the doping region and then forming the trench portion. The configuration of the trench portions passing through the doping region also includes a configuration of forming the trench portions and then forming the doping region between the trench portions.

As described above, the transistor portion 70 is provided with gate trench portions 40 and dummy trench portions 30. The diode portion 80 and the boundary region 200 of the present example are provided with the dummy trench portion 30, and are not provided with the gate trench portion 40. Note that the gate trench portion 40 may be arranged or the dummy trench portion 30 may be arranged at the boundary between the boundary region 200 and the transistor portion 70.

Note that the boundary region 200 is a buffer structure to arrange different structures in parallel, the transistor portion 70 and the diode portion 80. Therefore, the width of the boundary region 200 in the X axis direction may be short. For example, the boundary region 200 may be provided across about a width of one or more fourth mesa portions 64, or may not be provided.

The boundary region 200 may be provided broadly across a plurality of fourth mesa portions 64 in the X axis direction. This can suppress the transistor portion 70 affecting the characteristic of the diode portion 80, or suppress the operation of the gate trench portion 40 and the release or injection of holes of the contact region 15 affecting the forward voltage and reverse recovery characteristic, for example.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided inside the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the front surface 21 of the semiconductor substrate 10. The gate conductive portion 44 is electrically connected to a gate runner. When a predetermined gate voltage is applied to the gate conductive portion 44, a channel is formed by an electron inversion layer in a surface layer of the base region 14 at an interface in contact with the gate trench portion 40.

The dummy trench portion 30 may have the same structure as that of the gate trench portion 40 in the cross section. The dummy trench portion 30 has a dummy trench, a dummy dielectric film 32, and a dummy conductive portion 34 that are provided at the front surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 of the present example are covered with the interlayer dielectric film 38 at the front surface 21 of the semiconductor substrate 10. It should be noted that bottom portions of the dummy trench portion 30 and the gate trench portion 40 may be formed in a curved-surface shape (a curved-line shape in the cross section) convexly downward.

The second mesa portion 62 of the present example is provided with a trench contact portion 17. The trench contact portion 17 is a portion in which the front surface electrode (that is, the emitter electrode 52 or the contact plug portion) is provided inside the mesa portion. The trench contact portion 17 can be formed by forming a trench on the front surface 21 of the semiconductor substrate 10 exposed through the contact hole 54, and filling the front surface electrode inside the trench. In the second mesa portion 62, a region where the second mesa portion 62 and the front surface electrode are connected in the trench contact portion 17 corresponds to the contact portion.

The third mesa portion 63 of the present example is provided with the front surface contact portion 87 at which the front surface electrode is in contact with the front surface of the third mesa portion 63. The lower end of the front surface contact portion 87 is arranged above the lower end of the trench contact portion 17. The fourth mesa portion 64 of the present example may be provided with the trench contact portion 17, or may be provided with the front surface contact portion 87. Alternatively, a part of the fourth mesa portions 64 may be provided with the trench contact portion 17 while the other fourth mesa portions 64 may be provided with the front surface contact portion 87.

In the present example, each contact portion refers to an interface at which the front surface electrode and the mesa portion 60 are in contact with each other. The contact portion may include a surface of the front surface electrode and a surface of the mesa portion 60. Here, in case of the front surface contact portion 87, the surface of the mesa portion 60 refers to a front surface of the mesa portion 60, that is, the front surface 21 of the semiconductor substrate 10. In case of the trench contact portion 17, the surface of the mesa portion 60 refers to a bottom surface of the contact hole 54 provided inside the mesa portion 60. A width Wpcn of the front surface contact portion 87 of the present example in the X axis direction may be the same as or may be different from a width Wtcn of the trench contact portion 17 in the X axis direction, or may be greater than the width Wtcn.

Note that, when a metal silicide layer is formed on an interface between the front surface electrode and the mesa portion 60, the metal silicide layer may be included in the front surface electrode. That is, an interface between the metal silicide layer and the mesa portion 60 may be referred to as the contact portion.

At least a part of the mesa portions 60 may be provided with a plug region at a region in contact with the lower end of the contact portion. The plug region may be a region of the P++ type having a doping concentration higher than that of the contact region 15. In the example of FIG. 3A, a second plug region 222 is provided to be in contact with the front surface contact portion 87.

In the present example, the trench contact portion 17 provided in the transistor portion 70 facilitates to extract a minority carrier in the base region 14 (for example, a hole). This can improve the breakdown withstand capability such as a latch up withstand capability due to minority carriers. The trench contact portion 17 shown in FIG. 3A is provided up to a part of a depth of the emitter region 12, but not provided with the first plug region 221 at the bottom surface. In another example, the trench contact portion 17 may be provided up to the depth reaching the base region 14, and the first plug region 221 may be provided at the bottom surface of the trench contact portion 17.

In addition, the diode portion 80 of the present example is provided with the front surface contact portion 87, rather than the trench contact portion 17. When the trench contact portion 17 is provide, a region of the anode region 84 having a higher doping concentration in the vicinity of the front surface 21 of the semiconductor substrate 10 is remove such that the trench contact portion 17 is in contact with a region of the anode region 84 having a lower doping concentration. Then, the front surface contact portion 87 is provided in the third mesa portion 63 of the diode portion 80 so that the forward voltage of the diode portion 80 can be reduced.

A width Wpcn of the front surface contact portion 87 of the present example in the X axis direction is greater than the width Wtcn of the trench contact portion 17 in the X axis direction. This can further reduce the contact resistance of the front surface contact portion 87 and further lower the forward voltage of the diode portion 80.

The reverse recovery loss and the forward voltage of the diode portion 80 are in the trade off relationship. When the diode portion 80 is conductive, an increase in the hole injection lowers the forward voltage but increases the reverse recovery loss. On the other hand, an increase in the hole extraction reduces the reverse recovery loss but increases the forward voltage of the diode portion 80. In the present example, the transistor portion 70 is provided with the trench contact portion 17 and the diode portion 80 is provided with the front surface contact portion 87 such that the trade off between the reverse recovery loss and the forward voltage of the diode portion 80 can be improved.

FIG. 3B is an enlarged view of the vicinity of the second mesa portion 62 and the third mesa portion 63 shown in FIG. 3A. In FIG. 3B, one second mesa portion 62 and one third mesa portion 63 are shown, while a region between the mesa portions is omitted.

The emitter electrode 52 of the present example is provided on the front surface of the interlayer dielectric film 38. The contact plug portion 250 includes a plug 251 and a barrier metal portion 252. The plug 251 of the present example includes tungsten. The barrier metal portion 252 is provided above the front surface 21 of the semiconductor substrate 10. The barrier metal portion 252 is at least provided at the bottom surface of the contact hole 54. The barrier metal portion 252 may be provided at a lower end of each contact portion. The barrier metal portion 252 may be in contact with the semiconductor substrate 10. The barrier metal portion 252 may also be provided at a side surface of the contact hole 54. The plug 251 is embedded in the contact hole 54 via the barrier metal portion 252. The plug 251 and the barrier metal portion 252 may also be provided on the front surface of the interlayer dielectric film 38 or may not be provided.

The barrier metal portion 252 is formed of a material having a hydrogen absorbing capability higher than that of the emitter electrode 52. This suppresses a hydrogen ion entering the semiconductor substrate 10. The barrier metal portion 252 of the present example includes titanium. The barrier metal portion 252 may include a titanium nitride layer. The barrier metal portion 252 may also be a stacked film of a titanium layer and a titanium nitride layer.

The emitter electrode 52 is provided above the barrier metal portion 252. The emitter electrode 52 is also provided above the interlayer dielectric film 38. The emitter electrode 52 is formed of a material different from that of the barrier metal portion 252. As an example, the emitter electrode 52 includes aluminum. The emitter electrode 52 may be an alloy of aluminum and silicon.

A width Wpcn of the front surface contact portion 87 of the present example in the X axis direction is greater than the width Wtcn of the trench contact portion 17 in the X axis direction. This can reduce the contact resistance of the front surface contact portion 87 and lower the forward voltage of the diode portion 80.

The third mesa portion 63 may include a second plug region 222 of the P++ type provided to be in contact with a lower end of the front surface contact portion 87 and having a doping concentration higher than that of the anode region 84. The second plug region 222 may have a higher doping concentration than that of the contact region 15. The anode region 84 of the third mesa portion 63 may have a doping concentration lower than that of the base region 14 of the transistor portion 70. In this case, a hole injection from the third mesa portion 63 to the drift region 18 can be suppressed. The second plug region 222 of the present example may be provided to extend in the Y axis direction or may be provided discretely.

FIG. 3B shows a depth position Z1 of the trench contact portion 17 and a depth position Z2 of the front surface contact portion 87 in the Z axis direction. The depth positions of the trench contact portion 17 and the front surface contact portion 87 are the deepest position of an interface at which the semiconductor substrate 10 and a metal electrode (for example, the barrier metal portion 252, the emitter electrode 52 and the like) are in contact with each other at the bottom surface of the contact hole 54. The depth position may be a distance from the front surface 21 of the semiconductor substrate 10 in the depth direction (in the −Z axis direction). The depth position Z2 is arranged at a position shallower than the depth position Z1.

The depth position Z2 of the present example is positioned at a depth which is the same as the front surface 21 of the semiconductor substrate 10. In addition, the depth position Z1 of the present example is arranged at a position deeper than the front surface 21 of the semiconductor substrate 10. That is, the depth position Z1 is arranged at a position more spaced apart from the front surface 21 of the semiconductor substrate 10 than the depth position Z2.

In another example, the depth position Z2 may be a position between the depth position Z1 and the front surface 21 of the semiconductor substrate 10. In this case, assuming that the front surface 21 of the semiconductor substrate 10 is a reference, the depth position Z2 may be equal to or smaller than a half of the depth position Z1 or may be equal to or smaller than a quarter of the depth.

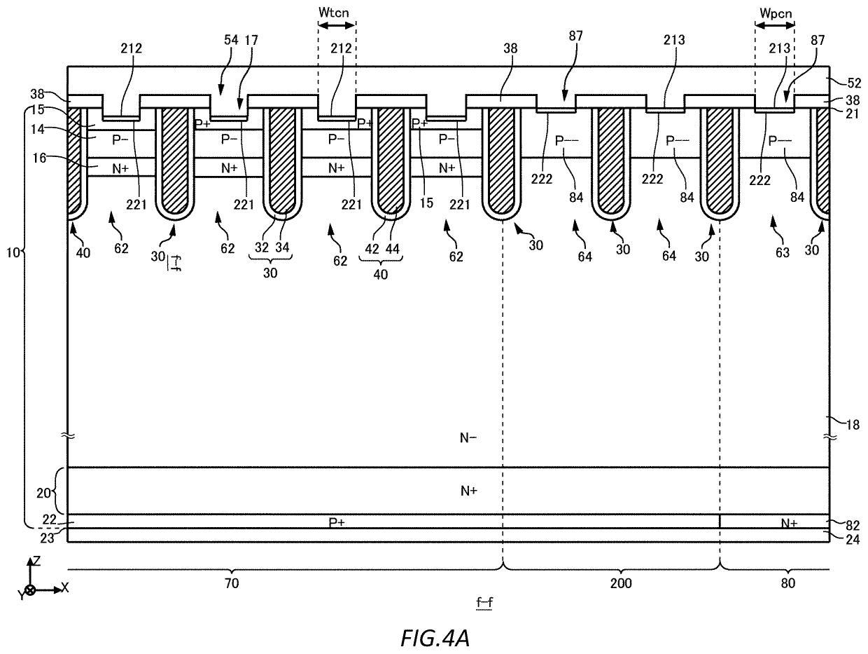

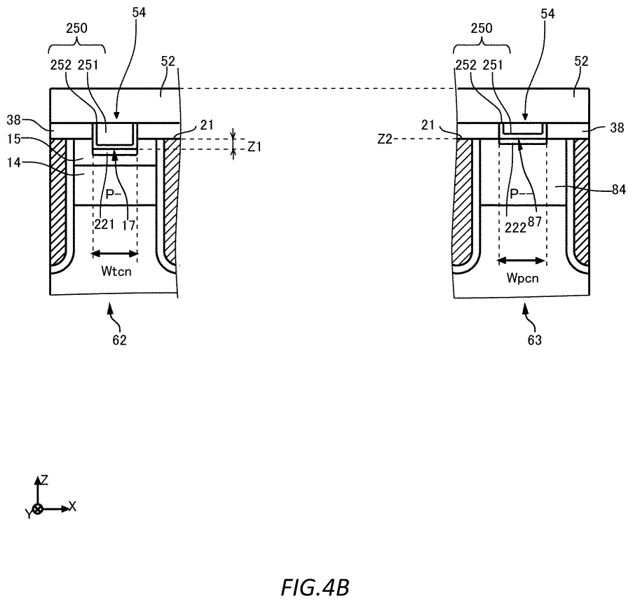

FIG. 4A is a diagram showing an example of a cross section f-f in FIG. 2. The cross section f-f is an XZ plane passing through the contact region 15 and the cathode region 82. In the cross section f-f, instead of the emitter region 12 on the cross section e-e shown in FIG. 3A, the contact region 15 is arranged. The other structure is similar to that of the cross section e-e. The structures of the trench contact portion 17 and the front surface contact portion 87 of the cross section f-f are similar to those of the cross section e-e.

The second mesa portion 62 of the present example includes a first plug region 221 of the P++ type provided to be in contact with the lower end of the trench contact portion 17 and having a doping concentration higher than that of the contact region 15. At least a part of the first plug region 221 is provided to overlap the contact region 15 in a top view. That is, the first plug region 221 is provided in any of the XZ cross sections passing through the contact region 15. The first plug region 221 may be provided in the XZ cross section passing through the center of the contact region 15 in the Z axis direction. The first plug region 221 may not be provided in some of the XZ cross sections pass the emitter region 12. For example, the first plug region 221 is not provided in the XZ cross section passing through the center of the emitter region 12 in the Z axis direction. The entire first plug region 221 may be provided to overlap the contact region 15. In this case, the first plug region 221 does not overlap the emitter region 12 in a top view, and the first plug region 221 is provided discretely in the Y axis direction. Each plug region is provided to facilitate to extract a hole in each mesa portion. For this reason, a decrease in the withstand capability can be suppressed.

FIG. 4B is an enlarged view of the vicinity of the second mesa portion 62 and the third mesa portion 63 shown in FIG. 4A. In FIG. 4B, one second mesa portion 62 and one third mesa portion 63 are shown, while a region between the mesa portions is omitted. The structure of the third mesa portion 63 is similar to the third mesa portion 63 shown in FIG. 3B.

The second mesa portion 62 includes the contact region 15 instead of the emitter region 12, with respect to the structure shown in FIG. 3B, and includes the first plug region 221 in contact with the lower end of the trench contact portion 17. The other structure is similar to that of the example of FIG. 3B.

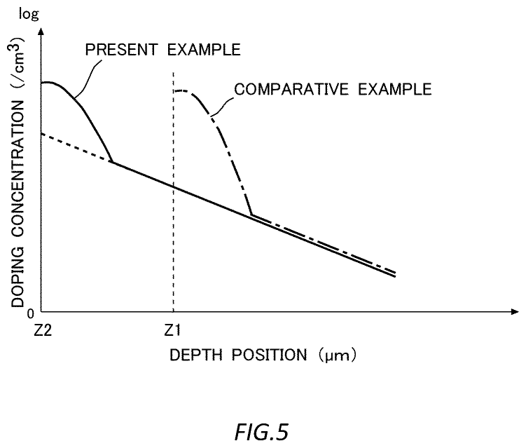

FIG. 5 is a diagram showing an example a P type doping concentration distribution of the anode region 84 and the second plug region 222 in the vicinity of the front surface of the third mesa portion 63. The vertical axis is a doping concentration distribution in the third mesa portion 63 while the horizontal axis is a depth position with reference to the front surface of the third mesa portion 63.

In FIG. 5, a P type doping concentration profile of the present example is indicated by a solid line. The depth position Z2 of the present example is positioned at a depth which is the same as that of the front surface 21. The P type doping concentration profile of the present example is formed of the anode region 84 formed by diffusing an impurity of the P type from the front surface 21 and the second plug region 222 formed by performing an ion implantation through the bottom surface of the contact hole 54.

In FIG. 5, a P type doping concentration profile of the comparative example is indicated by a dot-dashed line. The comparative example is a doping concentration profile when the third mesa portion 63 of the diode portion 80 is provided with the trench contact portion 17, like the transistor portion 70.

In the comparative example, a region of the anode region 84 having a higher doping concentration in the vicinity of the front surface 21 of the semiconductor substrate 10 is removed to provide the trench contact portion 17. The P type doping concentration profile of the comparative example is formed of the second plug region 222 formed by performing an ion implantation to the bottom surface of the contact hole 54 formed up to the depth position Z1 in the anode region 84.

The trench contact portion 17 is in contact with a region of the anode region 84 having a doping concentration lower than that of the front surface contact portion 87. Therefore, a hole injection is decreased such that the forward voltage is increased. Then, the front surface contact portion 87 is provided in the third mesa portion 63 of the diode portion 80 so that the forward voltage of the diode portion 80 can be reduced.

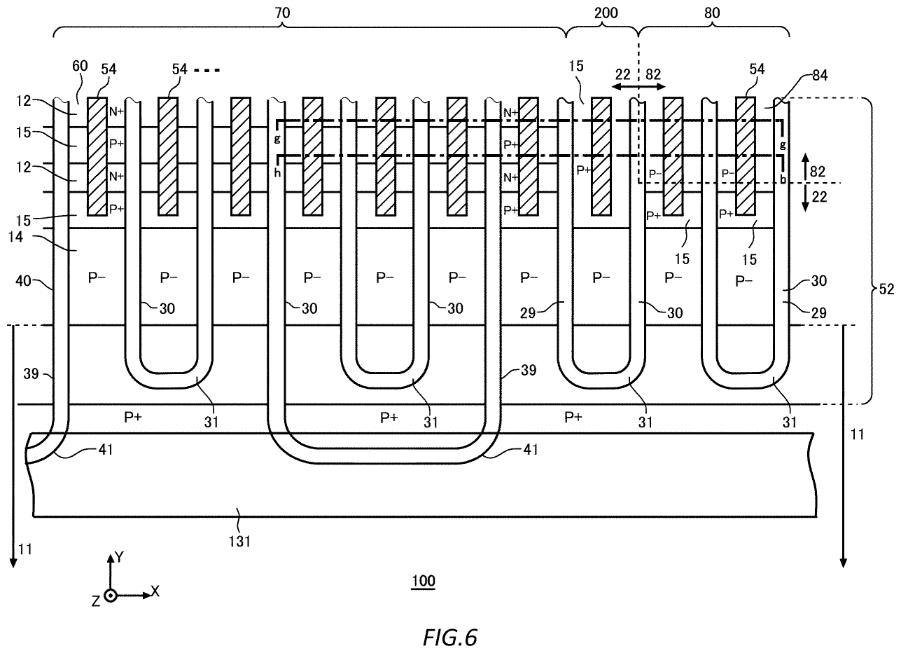

FIG. 6 is a plan view showing another example of FIG. 2. The present example is different from FIG. 2 in that the boundary region 200 includes one mesa portion 60 provided with the base region 14 in the front surface side and the contact region 15 provided at the front surface side of the base region 14. In addition, a doping concentration of the anode region 84 of the present example may be higher than a doping concentration of the anode region 84 of FIG. 2 and the same as a doping concentration of the base region 14. The anode region 84 of the present example is of the P− type.

In addition, the front surface side of the mesa portion 60 of the diode portion 80 is provided with the base regions 14 between which the anode region 84 is interposed while the contact region 15 is provided between the anode region 84 and the base region 14 in the Y axis direction. The contact region 15 may be provided to cover the end of the contact hole 54 in a top view.

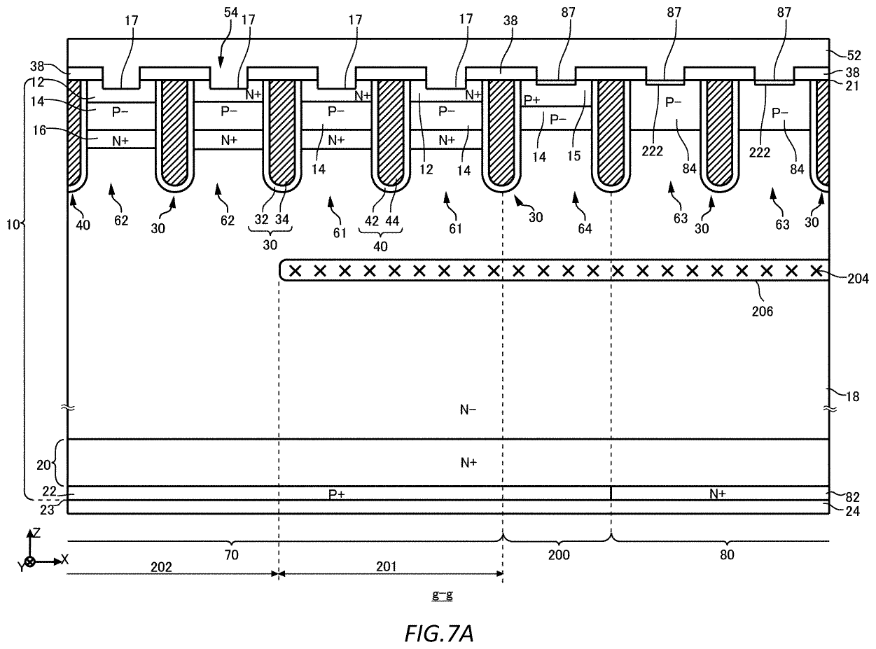

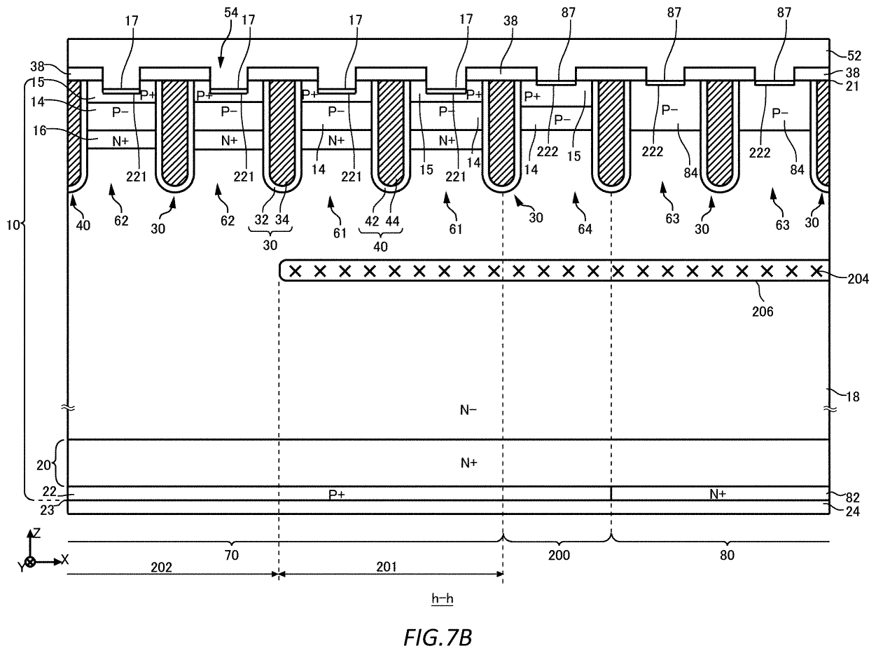

FIG. 7A is a diagram showing an example of a cross section g-g in FIG. 6. The cross section g-g is an XZ plane passing through the emitter region 12 and the cathode region 82. A semiconductor device 100 in the present example has a semiconductor substrate 10, an interlayer dielectric film 38, an emitter electrode 52, and a collector electrode 24 in the cross section.

The semiconductor device 100 of the present example includes a lifetime adjustment region 206 containing a lifetime killer that adjusts a lifetime of carriers. The lifetime adjustment region 206 of the present example is a region where a lifetime of charge carriers is locally small. The charge carriers are electrons or holes. The charge carriers may be simply referred to as carriers. The lifetime adjustment region 206 of the present example is formed by implanting charged particles such as helium from the front surface 21 side of the semiconductor substrate 10. In the present example, a concentration distribution of the charged particles such as helium in the depth direction of the semiconductor substrate 10 may have a tapered shape from the lifetime adjustment region 206 to the front surface 21 of the semiconductor substrate 10. That is, a concentration of the charged particles such as helium (/cm³) may be decreased monotonically from the lifetime adjustment region 206 to the front surface 21. The concentration of the charged particles such as helium on the front surface 21 may be larger than 0. On the other hand, a concentration of the charged particles such as helium in the direction from the lifetime adjustment region 206 toward the back surface 23 may also have a tapered shape. Note that the concentration of the charged particles such as helium is more sharply decreased in the taper toward the back surface 23 than in the taper toward the front surface 21. The concentration of the charged particles such as helium on the back surface 23 is lower than the concentration of the charged particles such as helium on the front surface 21. The concentration of the charged particles such as helium on the front surface 21 may be equal to or smaller than the measurement limit or may be 0. The lifetime adjustment region 206 may be formed by implanting charged particles such as helium from the back surface 23 side of the semiconductor substrate 10.

By implanting charged particles such as helium or the like into the semiconductor substrate 10, lattice defects 204 such as vacancies are formed in the vicinity of the implanting position. The lattice defects 204 generate recombination centers. The lattice defects 204 may be mainly composed of vacancies such as monatomic vacancies (V) or diatomic vacancies (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy-type lattice defects, vacancy-type defects, or simply lattice defects. In the present specification, the lattice defects 204 may be simply referred to as recombination centers or lifetime killers as recombination centers contributing to recombination of carriers. The lifetime killers may be formed by implanting helium ions into the semiconductor substrate 10. The helium chemical concentration may refer to the density of the lattice defects 204. Note that the lifetime killer formed by implanting helium may be terminated by hydrogen existing in the buffer region 20, so a depth position of the density peak of the lifetime killer and a depth position of the helium chemical concentration peak may not match. In addition, when implanting hydrogen ions into the semiconductor substrate 10, the lifetime killer may be formed in a passed-through region of hydrogen ions that is more on the implantation surface side than the projected range.

The lattice defect 204 is an example of the lifetime killer. In FIG. 7A, the lattice defects 204 at the implanting positions of the charged particles are schematically indicated by x marks. In a region where many lattice defects 204 remain, the carriers are captured by the lattice defects 204, and thus the lifetime of the carriers is shortened. By adjusting the lifetime of carriers, characteristics of the diode portion 80 such as a reverse recovery time and a reverse recovery loss can be adjusted. A position at which the carrier lifetime shows a local minimum value in the depth direction of the semiconductor substrate 10 may be set as the depth position of the lifetime adjustment region 206.

The lifetime adjustment region 206 is arranged in the front surface 21 side of the semiconductor substrate 10. The front surface 21 side refers to a region from the center position to the front surface 21 of the semiconductor substrate 10 in the depth direction of the semiconductor substrate 10. The lifetime adjustment region 206 of the present example is arranged below the lower end of the trench portion. In addition, when the lifetime adjustment region 206 is formed by irradiating a particle line such as an electron line having a higher penetration efficiency, the lattice defects are formed from the front surface 21 to the back surface 23 of the semiconductor substrate 10 in a substantially uniform manner. In this case, however, the depth position of the lifetime adjustment region 206 may be considered to be arranged in the front surface 21 side of the semiconductor substrate 10.

The lifetime adjustment region 206 may be provided in at least one of the transistor portion 70 and the diode portion 80. When the semiconductor device 100 includes the boundary region 200, the boundary region 200 may also be provided with the lifetime adjustment region 206. The lifetime adjustment region 206 may be provided across the entire diode portion 80 in the X axis direction. The lifetime adjustment region 206 may be provided in the entire boundary region 200. In another example, the lifetime adjustment region 206 may be provided in a part of the boundary region 200.

The lifetime adjustment region 206 of the diode portion 80 of the present example is provided to extend to a part of the transistor portion 70 in the X axis direction. The lifetime adjustment region 206 of the diode portion 80 and the lifetime adjustment region 206 of the transistor portion 70 are provided at the same depth position. In the transistor portion 70, a region in which the lifetime adjustment region 206 is provided refers to an adjustment region 201 while a region in which the lifetime adjustment region 206 is not provided refers to a no-adjustment region 202. The no-adjustment region 202 is a region in which a carrier lifetime at depth position which is the same as that of the lifetime adjustment region 206 is shorter than a carrier lifetime of the lifetime adjustment region 206 of the diode portion 80.

The no-adjustment region 202 may also be a region in which charged particles such as helium are not implanted to form a lifetime killer such as the lattice defect 204. The chemical concentration of the charged particles such as helium (/cm³) in the no-adjustment region 202 may be the same as the chemical concentration of the charged particles at the center of the drift region 18 in the Z axis direction.

The adjustment region 201 of the present example includes the trench contact portion 17 at which the first mesa portion 61 and the emitter electrode 52 are in contact with each other. The trench contact portions 17 may be provided for a part of the first mesa portions 61 or the trench contact portions 17 may be provided for all of the first mesa portions 61. Alternatively, the front surface contact portions 87 may be provided for all of the first mesa portions 61. The second mesa portion 62 of the no-adjustment region 202 has a structure which is the same as that of the second mesa portion 62 described in FIG. 3A, and therefore the description thereof is omitted. Note that the lifetime adjustment region 206 may not be extended to the transistor portion 70 while the adjustment region 201 may not be provided. Alternatively, the lifetime adjustment region 206 may be extended to the entire transistor portion 70 while the no-adjustment region 202 may not be provided.

A doping concentration of the anode region 84 may be the same as a doping concentration of the base region 14 or may be lower than a doping concentration of the base region 14. Alternatively, a doping concentration of the anode region 84 may also be higher than a doping concentration of the base region 14. The semiconductor device 100 of the present example includes the lifetime adjustment region 206 to reduce the reverse recovery loss of the diode portion 80 such that the doping concentration of the anode region 84 may be relatively higher.

The boundary region 200 of the present example includes one mesa portion 60 (the fourth mesa portion 64) provided with the base region 14 and the contact region 15 provided at the front surface side of the base region 14. The contact region 15 is interposed between the base regions 14 at the ends in the Y axis direction. This can facilitate to extract holes in the semiconductor substrate 10 via the mesa portion 60 (the fourth mesa portion 64) of the boundary region 200 to the emitter electrode 52 during the turn off operation. In addition, the lifetime adjustment region 206 is extended to the transistor portion 70 to provide the adjustment region 201 such that a hole injection from the contact region 15 can be suppressed. Therefore, in the X axis direction, the boundary region 200 may not be extended across a plurality of mesa portions 60, or alternatively, the boundary region 200 may not be provided.

Note that, as another example, a broad boundary region having a width spanning across a plurality of mesa portions 60 in the X axis direction can be provided in addition to the lifetime adjustment region 206 such that a hole injection from the mesa portion 60 (the first mesa portion 61, the second mesa portion 62 and the fourth mesa portion 64) is further suppressed to reduce a loss during the reverse recovery operation.

FIG. 7B is a cross section h-h including the contact region 15 in FIG. 6. The cross section h-h is an XZ plane passing through the contact region 15 and the cathode region 82. In the cross section h-h, the contact region 15 is arranged instead of the emitter region 12 in the cross section g-g shown in FIG. 7A. The other structure is similar to that of the cross section g-g. The structures of the trench contact portion 17 and the front surface contact portion 87 of the cross section h-h are similar to those of the cross section g-g.

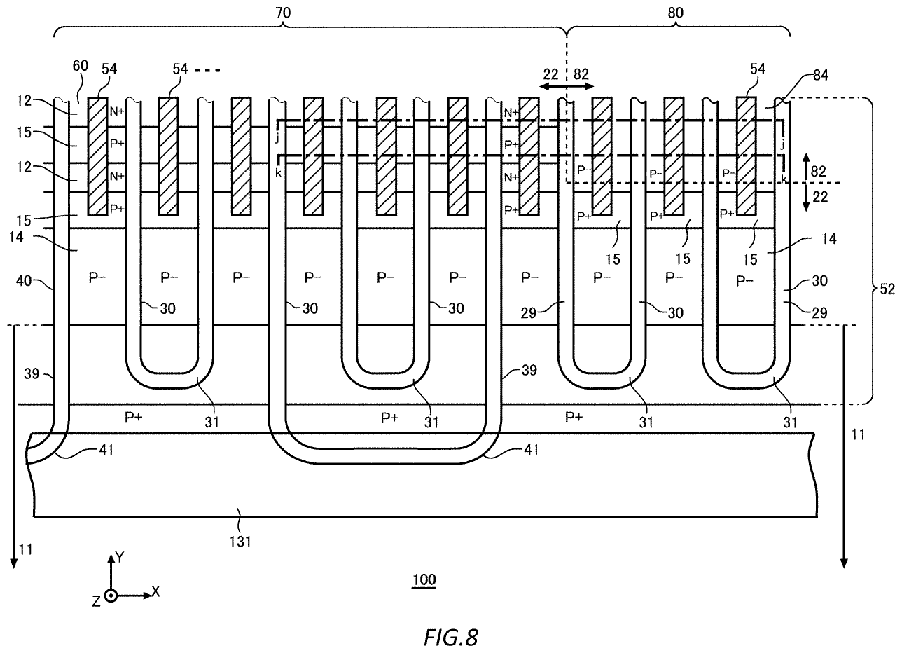

FIG. 8 is a plan view showing another example of FIG. 2. The present example is different from FIG. 2 in that the boundary region 200 is not provided. The semiconductor device 100 of the present example is mainly used for a resonant circuit and used under a condition that the reverse recovery operation is not performed.

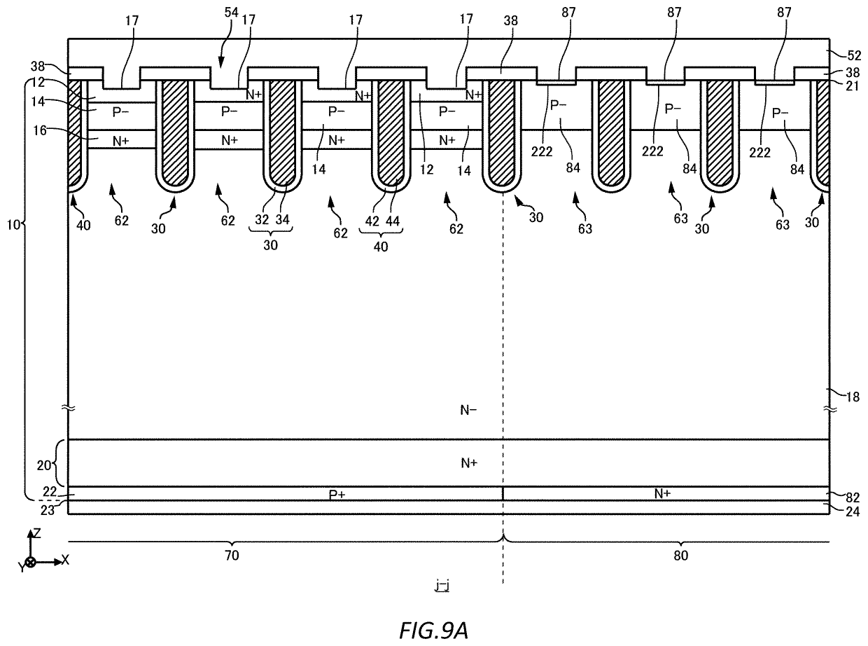

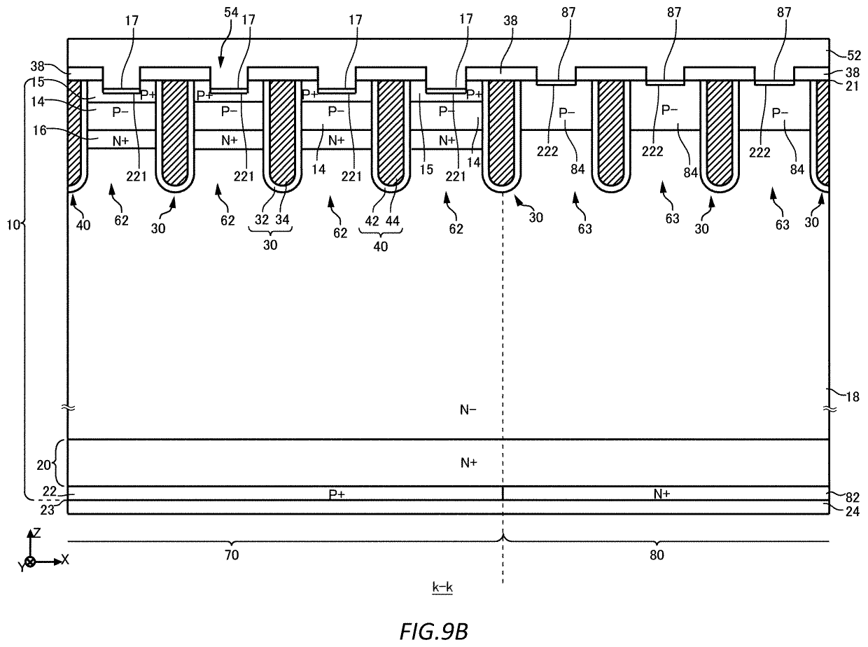

FIG. 9A is a diagram showing an example of a cross section j-j in FIG. 8. The cross section j-j is an XZ plane passing through the emitter region 12 and the cathode region 82. A semiconductor device 100 in the present example has a semiconductor substrate 10, an interlayer dielectric film 38, an emitter electrode 52, and a collector electrode 24 in the cross section.

The anode region 84 of the present example may have the same doping concentration as that of the base region 14 or may have a doping concentration higher than that of the base region 14. The anode region 84 of the present example is of the P− type. In addition, the anode region 84 may be formed simultaneously by an ion implantation to form the base region 14, the contact region 15 or the well region 11.

The second mesa portion 62 of the transistor portion 70 of the present example is provided with the trench contact portion 17. The third mesa portion 63 of the diode portion 80 of the present example is provided with the front surface contact portion 87.

Note that the boundary region 200 is not provided in the present example, while the boundary region 200 may be provided in another example. In this case, as is used under a condition that the reverse recovery operation is not performed, the boundary region 200 does not need to be provided to span a plurality of mesa portions 60 in the X axis direction to suppress a hole injection from the contact region 15 of the transistor portion 70, but may be formed to have a narrow width. For example, the boundary region 200 includes one fourth mesa portion 64 provided with the front surface contact portion 87 similar to FIG. 7A.

FIG. 9B is a diagram showing an example of a cross section k-k in FIG. 8. The cross section k-k is an XZ plane passing through the contact region 15 and the cathode region 82. In the cross section k-k, the contact region 15 is arranged instead of the emitter region 12 in the cross section j-j shown in FIG. 9A. The other structure is similar to that of the cross section j-j. The structures of the trench contact portion 17 and the front surface contact portion 87 of the cross section k-k are similar to those of the cross section j-j. Note that the diode portion 80 may include the third mesa portion 63 provided with the base region 14 and the contact region 15 provided in the front surface side of the base region 14.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each process performed by an apparatus, system, program, and method shown in the claims, embodiments, or diagrams can be realized in any order as long as the order is not indicated by “prior to,” “before,” or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 11: well region, 12: emitter region, 14: base region, 15: contact region, 16: accumulation region, 17: trench contact portion, 18: drift region, 20: buffer region, 21: front surface, 22: collector region, 23: back surface, 24: collector electrode, 29: linear portion, 30: dummy trench portion, 31: edge portion, 32: dummy dielectric film, 34: dummy conductive portion, 38: interlayer dielectric film, 39: linear portion, 40: gate trench portion, 41: edge portion, 42: gate dielectric film, 44: gate conductive portion, 52: emitter electrode, 54: contact hole, 60: mesa portion, 61: first mesa portion, 62: second mesa portion, 63: third mesa portion, 64: fourth mesa portion, 70: transistor portion, 80: diode portion, 81: extension region, 82: cathode region, 84: anode region, 87: front surface contact portion, 90: edge termination structure portion, 100: semiconductor device, 130: outer circumferential gate runner, 131: active side gate runner, 160: active portion, 162: end side, 164: gate pad, 200: boundary region, 201: adjustment region, 202: no-adjustment region, 204: lattice defect, 206: lifetime adjustment region, 221: first plug region, 222: second plug region, 250: contact plug portion, 251: plug, 252: barrier metal portion

What is claimed is:

1. A semiconductor device comprising:
a transistor portion;
a diode portion;
a plurality of trench portions provided on a front surface of a semiconductor substrate;
a drift region of a first conductivity type provided in the semiconductor substrate;
a base region of a second conductivity type provided above the drift region in the transistor portion;
an emitter region of the first conductivity type provided on the front surface of the semiconductor substrate in the transistor portion and having a doping concentration higher than that of the drift region;
a contact region of the second conductivity type having a doping concentration higher than that of the base region;
an anode region of the second conductivity type provided above the drift region in the diode portion;
a mesa portion of the semiconductor substrate provided between the plurality of trench portions;
an interlayer dielectric film provided above the semiconductor substrate;
a front surface electrode provided above the semiconductor substrate;
a trench contact portion at which the front surface electrode and the mesa portion are connected to each other in the transistor portion; and
a front surface contact portion at which the front surface electrode and the mesa portion are connect to each other in the diode portion,
wherein a lower end of the front surface contact portion is arranged above a lower end of the trench contact portion.

2. The semiconductor device according to claim 1, wherein
a width of the front surface contact portion in a trench array direction is greater than a width of the trench contact portion in the trench array direction.

3. The semiconductor device according to claim 1, wherein
the front surface electrode includes an emitter electrode.

4. The semiconductor device according to claim 3, wherein
the front surface electrode is provided in a contact hole of the interlayer dielectric film and includes a contact plug portion connecting the emitter electrode with the semiconductor substrate.

5. The semiconductor device according to claim 1, wherein
the doping concentration of the anode region is lower than the doping concentration of the base region.

6. The semiconductor device according to claim 1, wherein
the doping concentration of the anode region is the same as the doping concentration of the base region.

7. The semiconductor device according to claim 1, wherein
the doping concentration of the anode region is higher than the doping concentration of the base region.

8. The semiconductor device according to claim 6, wherein
the diode portion includes a lifetime control region provided in a side of the front surface, compared to a center of the semiconductor substrate in a depth direction of the semiconductor substrate.

9. The semiconductor device according to claim 7, wherein
the diode portion includes a lifetime control region provided in a side of the front surface, compared to a center of the semiconductor substrate in a depth direction of the semiconductor substrate.

10. The semiconductor device according to claim 1 comprising:
a first plug region of the second conductivity type provided at a lower end of the trench contact portion and having a doping concentration higher than that of the contact region; and
a second plug region of the second conductivity type provided in contact with a lower end of the front surface contact portion and having a doping concentration higher than that of the contact region.

11. The semiconductor device according to claim 10, wherein
the first plug region is provided discretely in a trench extending direction.

12. The semiconductor device according to claim 10, wherein
the second plug region is provided to extend in a trench extending direction.

13. The semiconductor device according to claim 1, comprising:
an accumulation region of the first conductivity type provided above the drift region in the transistor portion and having a doping concentration higher than that of the drift region.

14. The semiconductor device according to claim 1, comprising:
a boundary region provided between the transistor portion and the diode portion, wherein
in a top view, an area ratio of the emitter region in a mesa portion of the boundary region is smaller than an area ratio of the emitter region in a mesa portion of the transistor portion, and wherein
the mesa portion of the boundary region is provided with the front surface contact portion.

15. The semiconductor device according to claim 14, wherein
a width of the boundary region in a trench array direction is equal to or greater than 20 μm and equal to or smaller than 250μ m.
